(19) United States
(12) Patent Application Publication
(10) Pub. No.: US 2021/0331177 A1
(43) Pub. Date: Oct. 28, 2021

(54) Laboratory Device, In particular Magnetic Stirrer

(71) Applicant: Hans Heidolph GMBH, Kelheim (DE)

(72) Inventors: Walter Lohmann, Wendelstein (DE); Dirk Seifferth, Furth (DE)

(73) Assignee: Hans Heidolph GMBH, Kelheim (DE)

(21) Appl. No.: 16/344,136

(22) PCT Filed: Oct. 27, 2017
(86) PCT No.: PCT/EP2017/077760

§ 371 Date: Sep. 2, 2020

(30) Foreign Application Priority Data
Oct. 28, 2016 (DE) 10 2016 120 667.9

(51) Int. Cl. B01L 7/00; H01L 35/30

(52) U.S. Cl. CPC B01L 7/54; H01L 35/30; B01L 2400/043; B01L 2300/06; B01L 2300/0663; B01L 2300/1822

(57) ABSTRACT

A laboratory device includes an outer surface section. The laboratory device further includes a display apparatus that displays a respective temperature state of the outer surface section. In addition, the laboratory device utilizes at least also heat of the outer surface section for the energy supply of the display apparatus.

The present invention relates to a laboratory device, in particular to a magnetic stirrer, having an outer surface section, in particular a placement surface for a vessel, in particular a laboratory vessel.

An e.g. magnetic stirrer represents a typical laboratory device and serves to stir respective substances, in particular liquids, as part of the most varied laboratory applications. Since the substances to be stirred as part of laboratory applications can in particular, on the one hand, be aggressive materials, for example caustic or corrosive materials, that could damage components of the stirrer or, on the other hand, substances that can in turn react sensitively to foreign substances or have to be protected from contamination for another reasons, it is advantageous for a possibility to be present to separate the location of the stirring so-to say from the stirrer, in particular to provide said location outside the stirrer.

The magnetic drive of the magnetic stirrer is for this purpose configured to generate such a changing magnetic field that a magnetic stirring element, that can be placed directly into the laboratory vessel comprising the substance to be stirred, can be driven to make a stirring movement to stir the substance. Since the substance is received in the laboratory vessel that e.g. comprises glass or plastic as the material, a direct contact of the substance with the stirrer can be avoided. Only the magnetic stirring element that is separate from the stirrer and that can in particular be formed as a magnetic bar having a protective coating that is preferably inert and, for example, comprises polytetrafluoroethylene, (a so-called flea) is directly introduced into the substance to be stirred and can then be driven to make a stirring movement beyond the outer wall of the laboratory vessel by the magnetic field generated by the magnetic drive.

In this manner, only a respective magnetic stirring element that is simple to replace and in particular simple to clean comes into direct contact with the respective substance so that neither the magnetic stirrer is exposed to the respective substance nor can it contaminate the respective substance by contact with the magnetic stirrer.

The magnetic drive is preferably adjustable, i.e. can at least be switched on and off. The magnetic drive can, however, preferably also be adjusted beyond this. The magnetic drive can in particular also be adjustable with respect to the speed of the changing magnetic field and thus to the speed of the resulting stirring movement of the magnetic stirring element.

A large number of laboratory applications comprise a heating of a respective substance as a process step. Every direct manner of heat supply is to be understood by this that can e.g. serve for a preheating, a heating, a defrosting or a boiling of the respective substance. A respective laboratory device can comprise a heating apparatus for such a purpose. It can in particular be advantageous here also to stir the substance during heating to achieve a uniform heating of the substance over its total volume or also to simultaneously eliminate inhomogeneities of the substance by mixing. The laboratory device, in particular a magnetic stirrer, can therefore further comprise a heating apparatus, in particular an adjustable heating apparatus, that is configured to heat the outer surface section, in particular a placement surface, to heat the substance that is in particular arranged at the placement surface.

The magnetic drive and the heating apparatus of the magnetic stirrer are here preferably adjustable separately from one another, with the adjustability of the heating apparatus generally being able to be restricted, in a similar manner to the adjustability of the magnetic drive, to the possibility of switching the heating apparatus on and off. A substance arranged at the placement surface can thus be selectively stirred, heated or simultaneously stirred and heated. The heating apparatus is preferably variably adjustable beyond the simple switching on and off. A heating power of the heating apparatus can be settable, for example. The adjustability of the magnetic drive and/or of the heating apparatus can here be restricted to a respective value range, with the adjustment respectively being able to comprise a continuous and/or stepped adjustment.

The placement surface of the magnetic drive here represents that section of the magnetic stirrer at which a respective substance is arranged for stirring and/or heating. For this purpose, the placement surface is preferably horizontally aligned so that the substance, in particular a laboratory vessel containing the substance, can be simply placed onto the placement surface. On the one hand, the magnetic driving of the respective magnetic stirring element can substantially take place through the placement surface. On the other hand, the heating of the substance can take place in that the placement surface that is heated by the heating apparatus transmits heat to the substance, in particular via the laboratory vessel.

The placement surface can therefore become warm and possibly so hot during heating that a contact with the placement surface can cause pain or burns. The placement surface can, however, also become warm or hot with a magnetic stirrer without a heating function, for instance, in that a hot substance is arranged at the placement surface. As a rule it is here not possible to see from the placement surface itself what temperature it currently has. Particularly with a laboratory device such as a magnetic stirrer that is not used exclusively for heating, but that is frequently actually used without a heating function only within the framework of its basic function, that is for stirring, for example, there is therefore the risk of a painful burn if a user does not expect that a surface of the laboratory device could be hot. This risk is made even greater in that the surface can also still remain hot for a certain time when the heating apparatus has already been switched off and/or when the hot substance at the placement surface has already been removed so that a subsequent user has no recognizable reason to be careful of a possibly hot surface.

To reduce the risk of burns with a magnetic stirrer, in particular having a heating function, provision can therefore be made that the magnetic stirrer comprises a display apparatus that is configured to display a respective temperature state of the placement surface.

It is therefore possible to visually recognize from the display apparatus what temperature state of the placement surface is present. In particular at least two temperature states of the placement surface must be distinguished here. The two states are in particular a hot state in which the placement surface has a temperature in a range in which a contact with the placement surface should be avoided since the contact can be perceived as unpleasant or painful or even dangerous to the health and a cool state in which the placement surface has a temperature in a range in which a contact with the placement surface is not critical.

The respective temperature ranges of the temperature states distinguished by the display apparatus can in particular seamlessly adjoin one another and can be respectively separated by a predefined or predefinable temperature threshold value. A respective temperature state can in this manner be associated with the placement surface of the magnetic stirrer for any temperature and can then be made visible by the display apparatus. It is possible to indicate the respective temperature of the placement surface with differently fine gradations here depending on the number of distinguished temperature states.

A displayed temperature state is here in particular correlated with the temperature of the placement surface, but generally independent of a heating state of the heating apparatus. For the display apparatus should advantageously be able to warn of the actual risk of burns, and indeed also when, for instance, the heating apparatus is switched off and/or the magnetic stirrer has been fully disconnected from the power grid, e.g. on a sudden blackout. Conversely, it can be advantageous if it can, for instance, also be recognized through the display apparatus how long the placement surface can still be touched without danger with a heating apparatus that is already heating.

It can, however, be problematic with such a magnetic stirrer having a display apparatus for displaying a respective temperature status of the placement surface that the display apparatus requires a power supply as a rule. The display apparatus cannot warn of the heated placement surface if the power supply for the display apparatus is simultaneously also ended, however, after a heating of the placement surface, for instance on a switching off or to switch off the heating apparatus. It can thus in particular also occur when the magnetic stirrer is completely switched off as a whole or when a blackout occurs, that the display apparatus does not indicate a hot state of the placement surface even though the placement surface is still hot.

As explained above, the initially named laboratory device can be a magnetic stirrer, but can, for example, also be an evaporator, in particular a rotary evaporator, or a shaking and/or mixing device. The outer surface section is in particular a section of the outer surface of the laboratory device. The outer surface section can be a placement surface (in particular in the case of a magnetic stirrer and/or of a shaking and/or mixing device) or a receiver surface of a heating bath for receiving a heating bath liquid (in particular in the case of a rotary evaporator).

It is an object of the invention to provide a laboratory device, in particular a magnetic stirrer, that has improved safety.

The object is satisfied by a laboratory device having the features of claim 1 and in particular in that the laboratory device is configured to at least also use heat of the outer surface section, in particular the placement surface, for the energy supply of the display apparatus.

The display apparatus can generally be connected to a general power supply of the laboratory device, in particular of the magnetic stirrer, that also, for instance, feeds a magnetic drive and/or an optional heating apparatus. Provision is, however, made with the laboratory device in accordance with the invention that the display apparatus can at least also be supplied with energy in a different manner, namely by using the heat of the outer surface section. This type of energy supply can be provided in addition to said general power supply to so-to-say step in in the event of a failure or of a complete switching off of the power supply. It is, however, also possible that the display apparatus is only supplied with energy by the utilization of the heat of the outer surface section. For since the display apparatus is in particular configured to warn of a hot or heated outer surface section, it can be sufficient to only supply the display apparatus with energy when the outer surface section has a sufficient heat therefor. In both cases, the utilization of the heat of the outer surface section can have the result of or can at least contribute to the display apparatus being decoupled from the general power supply and thus generally being autonomous, from which an improved safety of the laboratory device results.

The display apparatus can in particular be directly caused to display a temperature state corresponding to a high temperature (hot state) in that it is supplied with energy from the then high heat of the outer surface section. At a lower temperature, in contrast, the heat of the outer surface section may be insufficient for an operation of the display apparatus so that the temperature state corresponding to this lower temperature (cool state) can actually be recognizable by the inactivity of the display apparatus.

In accordance with a particularly simple embodiment, the display apparatus—fed by the heat of the outer surface section—can, for instance, light up as long as the outer surface section exceeds a critical temperature and can otherwise be extinguished—due to a lack of sufficient heat for a sufficient energy supply. A detection and evaluation of the current temperature of the outer surface section and a control of the display apparatus dependent on the evaluation to output a corresponding signal is then not required. It can be seen from this that the utilization of the heat of the outer surface section for the energy supply of the display apparatus is not only advantageous to the extent that the display apparatus can thereby be independent of the general power supply, but also to the extent that a separate detection of the temperature of the outer surface section can be dispensed with.

In accordance with an advantageous embodiment, the laboratory device comprises a heat dissipation apparatus for the outer surface section and is configured to utilize a temperature gradient between the outer surface section and the heat dissipation apparatus for the energy supply of the display apparatus. Such a heat dissipation apparatus can be configured, e.g. for a typical magnetic stirrer having a heating function, for the heat dissipation from the placement surface. A laboratory device can e.g. comprise a heating apparatus having a hotplate at which a placement surface can be formed and which is arranged via a foot section at a base unit of the laboratory device. The foot section can then act as a heat dissipation apparatus due to its thermal conductivity so that a temperature gradient is formed along it that can be utilized for the energy supply of the display apparatus. Such a temperature gradient can, for instance, be converted by using the Seebeck effect into electrical voltage by which the display apparatus can then be supplied with power. In accordance with the Seebeck effect, an electrical voltage is produced in a circuit of two different electrical conductors on a temperature difference between the contact points.

In accordance with a further advantageous embodiment, the laboratory device can comprise an energy converter that is configured to convert heat of the outer surface section into energy that can be used for the energy supply of the display apparatus and to supply said energy to the display apparatus. This energy into which the heat is converted is in particular electrical energy. In general, however, a different kind of energy conversion can also be considered such as into chemical energy or radiation energy by means of which the display apparatus can be made to display a temperature state. The display can, for example, use thermochromic substances whose colors depend on their respective temperatures. Such a display apparatus based on a thermochromic color change can in particular also be provided at a vessel of the laboratory device in which a substance to be stirred can be received.

Said energy converter can in particular tap said temperature gradient. For this purpose, the energy converter is preferably in a thermal relationship, in particular in thermal contact, with the outer surface section, on the one hand, and with said heat dissipation apparatus, on the other hand. The energy converter can, for example, be in contact with a hotplate of a heating apparatus, on the one hand, and can be in contact with said foot section of the heating apparatus, on the other hand. It is advantageous here if the heat dissipation from the outer surface section extends at least to a substantial extent, in particular substantially completely (apart from a heat radiation into the general environment, for instance), over the energy converter so that the energy converter can to this extent also be integrated in the heat dissipation apparatus. In this manner, after the heating up of the outer surface section, its residual thermal energy can be ideally utilized by the energy converter.

In accordance with a preferred embodiment, the energy converter is configured as a thermoelectric generator, in particular in the manner of a Peltier element. The use of a Peltier element that can be acquired as a finished element enables a simple construction implementation of the laboratory device in accordance with the invention. A conventional laboratory device can in particular also be retrofittable in a simple manner by arranging such a Peltier element in the region of the outer surface section and of a display apparatus that can, for example, be configured as a simple LED lamp.

In some thermoelectric energy converters, in particular with Peltier elements, the direction of the energy conversion can be reversed. That is, thermal energy can alternatively be converted into electrical energy or electrical energy can be converted into thermal energy. Provision can therefore be made in a further embodiment of the laboratory device that said energy converter is not only configured for the conversion of thermal energy into electrical energy to supply the display apparatus, but also for the conversion of electrical energy that it, for instance, receives from a current or voltage supply of the laboratory device into thermal energy that can then be transferred to the outer surface section. The energy converter can therefore simultaneously also act as a (single or additional) heating element of an optionally provided heating apparatus. When the heating apparatus is switched on, the energy converter thus heats the outer surface section whose residual thermal energy it can at least partly recover and supply to the display apparatus after the switching off of the heating apparatus to warn of the hot outer surface section.

By using the heat of the outer surface section for the energy supply of the display apparatus, the latter is advantageously not reliant on the general power supply of the laboratory device. Provision can nevertheless be made that the display apparatus can additionally also be supplied with energy from a further source, in particular from the general power supply of the laboratory device. This is in particular of advantage when the display apparatus should not only be active, e.g. light up, when the outer surface section is hot, but should also display information in other cases.

In accordance with an advantageous embodiment, the display apparatus is configured also to display a respective heating state of a heating apparatus of the laboratory device. The laboratory device could generally comprise a further display apparatus to display a respective heating state, that is in particular to display whether the heating apparatus is switched on and whether the outer surface section is currently actively heating or is switched off. A respective temperature state of the outer surface section and a respective heating state of the heating apparatus are advantageously, however, indicated by the same display apparatus. Different information can also be displayed in a combined, in particular superposed, form here, for example in that a flashing start or stops, that a color change takes place, or that acoustic feedback takes place in addition to a visual display. The display apparatus can thus be configured as particularly compact and fewer components are required for the laboratory device.

The display apparatus can generally display respective temperature states of the outer surface section and respective heating states of the optionally provided heating apparatus spatially and/or temporally separately from one another. The display of respective temperature states and of respective heating states, however, preferably takes place in a combined manner, that is in particular at least overlapping in space and time. For example, different combinations of a respective temperature state and a respective heating state can be indicated by different visual signals so that a conclusion can be drawn both on the respective temperature state of the outer surface section and on the respective heating state of the heating apparatus from a single signal in each case.

Since the temperature state of the outer surface section and the heating state of the optionally provided heating apparatus can vary over time, the respective currently present temperature state and the respective currently present heating state are called the “respective” temperature state and the “respective” heating state respectively.

The display of a respective temperature state can take place in a large number of different manners in principle. For example, different states can be represented by different symbols of which a respective one or more can be displayed by the display apparatus. The display apparatus can, for example, comprise a monitor-like display field, for instance an LCD or TFT screen, for this purpose. A hot state can here e.g. be represented by a warning symbol. It is furthermore conceivable that different temperature states are shown in accordance with their respective temperature range by incremental symbols, for instance by a different number of lines or by bars of different lengths.

It is, however, in particular advantageous with respect to an energy supply by the residual heat of the outer surface section if the display apparatus has a small complexity to be able to be perceived as fast and as unambiguously as possible. It is preferred in this connection if the display apparatus comprises an illumination element controllable to transmit light and is configured to control the illumination element to transmit light having a respectively different illumination characteristic to indicate different temperature states of the outer surface section and/or different heating states of the heating apparatus. A plurality of different temperature states and optionally also a plurality of different heating states can thus be indicated by transmitting a respective specific illumination characteristic by the same illumination element. Such an embodiment is preferred.

The illumination element can, for example, be a signal light, for instance a lamp. The illumination element can also comprise an illumination surface that can in particular be backlit by a light source. Such an illumination surface can then have a shape that can be selected with respect to good perceptibility and/or a pleasing design. A symbol can in particular also be represented by the shape of an illumination surface of the illumination element, for instance in that the illumination surface is shaped in the manner of a warning triangle and/or of a flame to warn of a hot outer surface section.

Different illuminants can be considered as the light source of the illumination element. Since thermoelectric generators have a small efficiency and the residual heat present at the heated outer surface section is limited, light sources are preferred that enable an operation of the display apparatus with comparatively little energy. At least one LED is therefore preferably provide as the light source of the illumination element due to its low power requirements and the small heat radiation. The illumination element can, however, in particular also comprise a different kind of electroluminescent element as the light source.

In this embodiment, a plurality of different respective temperature states of the outer surface section can preferably be indicated by the same illumination element so that the temperature states cannot be distinguished with respect to different illumination elements. They can, however, instead be identified with respect to different illumination characteristics transmitted by the illumination element. In this respect, a specific kind of transmission of light by the illumination element is called an illumination characteristic for a respective state. Respective illumination characteristics for indicating different temperature states of the outer surface section can in particular be distinguished with respect to the respective duration, pulse frequency, pulse duration, pulse break duration, pulse sequence, spatial extent, color, color sequences, color changes, and/or brightness of the transmitted light.

For example, a temperature state corresponding to a high temperature can be indicated by brighter light than a temperature state corresponding to a lower temperature. In a similar manner, a temperature state can be indicated by a respective specific color of the transmitted light, with e.g. a progression from green over yellow and orange to red being able to correspond to ever high temperatures of the outer surface section, and vice versa. The light here does not have to be continuously transmitted, but can rather be differently pulsed depending on the indicated state. It is hereby generally possible to encode a plurality of different states by a respective different pulse sequence, for instance in the manner of Morse.

However, temporal patterns having a small complexity are to be preferred for a simple identification of the respective indicated state. A simple, in particular at least substantially linear, relationship between the pulse frequency, the pulse duration (duration of a single pulse) and/or the pulse break duration (duration of the time period between two pulses) and a mean temperature of the respective temperature state of the outer surface section can in particular be present.

A regular increase and decrease of the intensity of the transmitted light is in particular here to be understood as a pulsating or pulsed transmission of light. The intensity here in particular drops to zero between two pulses. The transition between the maximum and minimum intensities can be abrupt in the manner of a step function (which can correspond to a flashing) or can take place continuously, for example in the manner of a triangular function, saw tooth function, or sine function.

In accordance with an advantageous further development, the display apparatus is configured to control the illumination element to transmit light in accordance with a first illumination characteristic, in particular constantly illuminating light, for the display of a switched on state of the heating apparatus; to control illumination element to transmit light in accordance with a second illumination characteristic, in particular pulsating light, for a combined display of a switched off state of the heating apparatus and a hot state of the outer surface section; and/or to control the illumination element to transmit light in accordance with a third illumination characteristic, in particular no light, for a combined display of a switched off state of the heating apparatus and a cool state of the outer surface section. The transmission of the second illumination characteristic can here in particular be fed by the utilization of the heat of the heated outer surface section. The transmission of the first illumination characteristic can be fed, for example, by a general power supply of the laboratory device.

In this embodiment, a combined display of the respective temperature state of the outer surface section and of the respective heating state of the heating apparatus therefore takes place. A distinction can in particular be made here with reference to the respective mutually different illumination characteristics as to whether the heating apparatus adopts the switched on state in which light in accordance with the first illumination characteristic is transmitted or the switched off state. If the heating apparatus adopts the switched off state, a distinction can further be made with reference to respective further illumination characteristics between at least one hot state and a cold state of the outer surface section.

Provision can be made here that as long as the switched on state of the heating apparatus is present, that is the heating apparatus is switched on, the respective temperature state of the outer surface section is not displayed. The illumination element can here rather illuminate or can be switched off continuously and independently of respective temperature states of the outer surface section in accordance with the first illumination characteristic.

The first illumination characteristic preferably comprises the fact that the illumination element illuminates constantly, that is with an unchanging intensity, in a non-pulsated manner, in one color, e.g. red. It hereby becomes clear in a simple manner that heating is actually taking place and a contact of the outer surface section should therefore be avoided.

Unlike a simple indication of function of the heating apparatus that illuminates during heating and is completely extinguished on a switching off of the heating apparatus, the illumination element in this embodiment, however, also transmits light when the heating apparatus is switched off and thus adopts its switched off state and/or is completely taken off the power grid, e.g. due to a blackout. This further transmission of light takes place here for so long as the outer surface section still adopts the hot state, that is a state in which the outer surface section is still so hot that it should not be touched. However, so that it becomes clear that the outer surface section still only irradiates its residual heat, but is no longer actively heated, the illumination element now transmits light with a changed illumination characteristic, namely in accordance with the second illumination characteristic.

The second illumination characteristic preferably comprises pulsating light. Since the intensity of the transmitted light is not constant here, but rather increases and decreases regularly, this illumination characteristic can be distinguished in a simple manner from the first illumination characteristic of the switched on heating state.

Only when the outer surface section adopts the cool state, that is has in particular cooled below a predefined temperature threshold, below which a contact of the outer surface section is unproblematic, is the light in accordance with a third illumination characteristic transmitted. The cool state of the outer surface section and the switched off state of the heating apparatus is thus simultaneously indicated by this illumination characteristic in accordance with which the illumination element preferably does not transmit light. The transition between the second illumination characteristic and a third illumination characteristic not transmitting any light can here directly result from the fact that the residual heat of the outer surface section has reduced so much that the remaining heat, from which a danger no longer emanates, is no longer sufficient for the further energy supply of the display apparatus.

In principle, even further illumination characteristics can be provided for characterizing further states. It can, for example, be advantageous also to distinguish between at least a hot state and a cool state of the outer surface section by different illumination characteristics in the switched on state of the heating apparatus. More than one hot state of the outer surface section can furthermore be distinguished in that a respective different illumination characteristic is associated with each hot state. A gradual change of the temperature state of the outer surface section is then preferably indicated by a change of the transmitted illumination characteristic that is gradual in a comparable manner so that the change can be particularly intuitively understood.

In accordance with a further advantageous development, the display apparatus is configured to control the illumination element to transmit pulsating light of a different pulse frequency for a combined display of a switched off state of the aforesaid heating apparatus and different hot states of the outer surface section. The pulse frequency of the transmitted light here therefore depends on the respective hot state of the outer surface section. Hot states that correspond to hotter temperatures can in particular have a higher pulse frequency than hot states that correspond to lower temperatures. An intuitive understanding of the respective temperature state of the outer surface section is hereby made possible. In addition, faster pulse frequencies are as a rule perceived more easily and faster so that the perception of the display apparatus is advantageously the easier, the higher the temperature of the outer surface section and thus the risk for a user is. The temperature of the outer surface section can generally be made recognizable in any desired fine gradations depending on the number of different hot states of the outer surface section.

In the above-explained embodiments, the respective illumination characteristics in the above-explained embodiments can be additionally different, in particular in color, for instance, for a further clarification of respective states of the laboratory device so that, for example in the switched on state of the heating apparatus and in the hottest of the hot states of the outer surface section, the illumination element transmits red light and the color changes, for example, from red over orange to yellow with a decreasing pulse frequency by which a temperature decrease is signaled.

In accordance with a further advantageous embodiment, the laboratory device comprises an actuation element, in particular for switching and/or adjusting the heating apparatus, with the display apparatus being provided at the actuation element. The display apparatus can in particular be arranged encompassing the actuation element or can be integrated into the actuation element. Such an actuation element can serve only for the switching of the heating apparatus, that is can be functionally restricted to switching the heating apparatus on or off. The actuation element can, however, also serve to adjust the heating apparatus beyond this, that is, for instance, to set a heating power of the heating apparatus. The actuation element that has to be actuated manually as a rule can, for example, be a rocker switch, a push button, a rotary knob, or similar, with such actuation elements also being able to be implemented or reproduced by touch-sensitive, in particular capacitive, input elements such as touch elements. The input elements can generally here also be configured as removable operating elements. Since the actuation element is at least configured to switch the heating apparatus on and off, preferably also to make a further adjustment of the heating apparatus, a spatially directly visual and/or acoustic feedback of the respective adjustment can take place in that the display apparatus is provided at the actuation element.

The actuation element can for this purpose be surrounded at a plurality of sides by the display apparatus, in particular by an illumination surface or by said illumination element of the display apparatus, with the display apparatus not necessarily having to surround the actuation element over the full periphery. Alternatively or additionally, the display apparatus can be integrated in the actuation element, for instance in that the actuation element is at least regionally transparent and this region is backlit so that the region acts as an illumination surface of the display apparatus.

In accordance with a further embodiment, the laboratory device comprises a temperature sensor for detecting a respective temperature of the outer surface, section wherein the display apparatus is configured to determine and display the respective temperature state of the outer surface section in dependence on the respective temperature detected by means of the temperature sensor. A simple platinum measuring resistor can be used as the temperature sensor, for example. The temperature sensor preferably generates a signal that represents the respective temperature of the outer surface section and that is received by the display apparatus or by a control apparatus of the display apparatus. The respective temperature state of the outer surface section can be determined there in that a respective temperature state is selected from predefined temperature states with reference to the signal. This temperature state can then be subsequently displayed, for example in that the illumination element is controlled to transmit a respective illumination characteristic associated with this temperature state.

In accordance with a further embodiment, the laboratory device comprises a base unit having a common power supply for an optional magnetic drive, for the heating apparatus, and for the display unit, with the heating apparatus, in particular a hotplate, being formed separately from the base unit, being arranged at the base unit, and having the outer surface section. The display apparatus is then preferably provided at the base unit.

Said actuation element can in particular be provided at the base unit and the display apparatus can then, as explained further above, be provided at the actuation element. It is admittedly generally also possible to provide the display apparatus directly at the heating apparatus so that the temperature state of the outer surface section can advantageously be displayed close to or even in the outer surface section itself. The arrangement of the display apparatus at or in the base unit in contrast has the advantage that it is there exposed to at least a smaller degree to the heat generated by the heating apparatus.

A laboratory device in accordance with the invention provides greater security from accidentals burns by a simple, optionally also retrofittable display apparatus, with respect to conventional laboratory devices, in particular conventional laboratory devices with and without a heating function. This display apparatus that can generally also be provided in or at a vessel of the laboratory device permits a user of the laboratory device to recognize in a fast and intuitive manner whether the outer surface section still has residual heat from a preceding heating, and indeed even when the laboratory device has already been completely switched off. In general, such a residual heat display in accordance with the invention can also be provided while using the residual heat as an energy source, in particular with a magnetic stirrer, but also with other typical laboratory devices, in particular if they also have an additional heating function in addition to a basic function or with containers without any heating function of their own.

The present invention in particular relates to a magnetic stirrer having a magnetic drive and a placement surface for a vessel, in particular a laboratory device, having a substance to be stirred, wherein the magnetic drive is configured to generate a changing magnetic field such that a magnetic stirring element in the vessel can thereby be driven to make a stirring movement to stir the substance, wherein the magnetic stirrer comprises a display apparatus that is configured to display a respective temperature state of the placement surface, and wherein the magnetic stirrer is configured to utilize at least also heat of the placement surface for the energy supply of the display apparatus. The magnetic stirrer preferably comprises a heating apparatus that is configured to heat the placement surface to heat the substance.

The invention will be described in more detail in the following only by way of example with reference to the Figures.

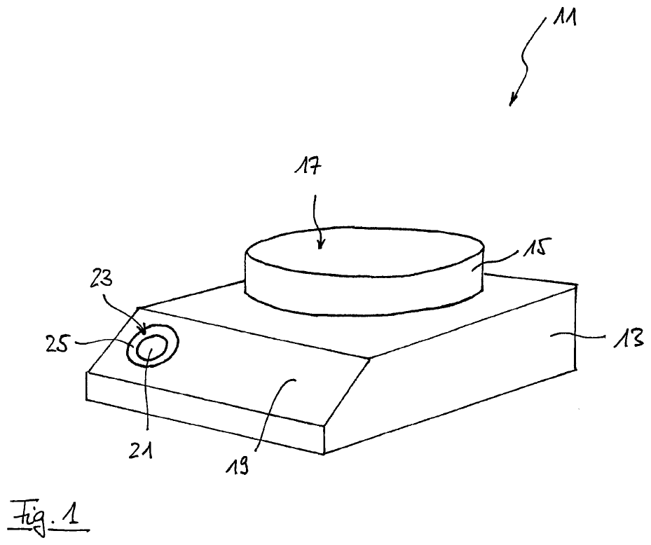

FIG. 1 shows a possible embodiment of a magnetic stirrer in accordance with the invention in a very simplified schematic representation; and

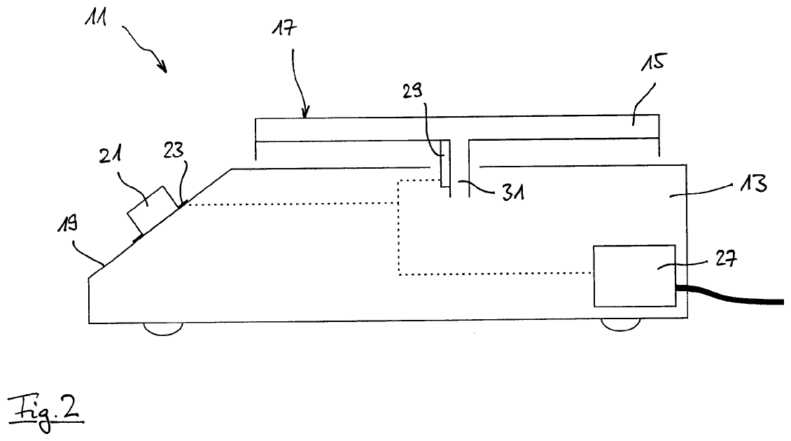

FIG. 2 shows a possible embodiment of a magnetic stirrer in accordance with the invention in a schematic side view.

A magnetic stirrer 11 is shown in very simplified form in FIG. 1 as an example of a laboratory device having a residual heat display in accordance with the invention. The magnetic stirrer 11 comprises a base unit 13. A heating apparatus 15 is arranged at the upper side of the base unit 13. The upwardly facing front section of this shape is configured as a hotplate that can be heated. The front face of the cylindrical shape simultaneously forms a placement and heating surface 17 of the magnetic stirrer 11.

A vessel, in particular a laboratory vessel, comprising a substance to be stirred and/or to be heated can be placed on the placement surface 17 that, on a conventional arrangement of the magnetic stirrer 11 with its lower side on a planar surface such as a tabletop, is horizontally aligned. For the stirring of the substance, a magnetic stirring element, in the manner of a so-called flea, for instance, is introduced into the substance and can be driven through the lower side of the vessel to make a stirring movement.

A magnetic drive, not visible from the outside, is provided in the interior of the magnetic stirrer 11 for this purpose. It is configured to generate a magnetic field in a region adjacent to the placement surface and above the placement surface, said magnetic field then being able to exert magnetic forces on the magnetic stirring element, in particular such that the magnetic stirring element at least substantially rotates about the cylinder axis of the cylindrical shape of the heating apparatus 15. In this manner, a stirring movement of the magnetic stirring element can be induced in the middle of the substance to be stirred by the magnetic drive provided in the interior of the magnetic stirrer 11.

The heating apparatus 15 that can extend at least partly also into the interior of the magnetic stirrer 11 comprises at least one electrical heating element that thermally contacts the placement surface 17. The heating apparatus 15 can heat the placement surface 17 in this manner so that then heat can be transmitted from the placement surface 17 to the respective substance placed on the placement surface 17 to heat the substance. So that the placement surface 17 is heated as homogeneously as possible, at least said front side of the cylindrical shape of the heating apparatus 15 comprises a material having a high thermal conductivity, in particular a metal. To avoid heat from being transferred from the placement surface 17 to the base unit 13, a gap can be provided between a lower edge of the jacket surface of the cylindrical shape and the upper side of the base unit 13.

The magnetic drive and the heating apparatus 15 are supplied with power by a common power supply 27 that is integrated in the base unit and has a connector for connecting a power plug (cf. FIG. 2), with generally a separate power supply also being possible. The magnetic drive and the heating apparatus 15 are adjustable at least to the extent that they can generally be switched on and off independently of one another to selectively stir and/or heat the respective substance.

The front surface of the base unit 13 forms an operating surface 19 of the magnetic stirrer 11 at which a plurality of actuation elements 21 are arranged for the adjustment of the magnetic stirrer 11. The actuation elements 21 in particular serve to switch the magnetic drive on and off and to set a speed of change of the magnetic field to thereby set the speed of the stirring movement or to switch the heating apparatus 15 on and off and to set a heating power of the heating apparatus 15 to regulate the speed of the heating or to reach a predefined and/or set desired temperature in the hotplate and/or medium.

Only a single one of these actuation elements 21 is shown that is formed as a flat push button or as a touch element and by whose actuation the heating apparatus 15 can be alternately switched on and off. A display apparatus 23 of the magnetic stirrer 11 is provided at the push button 21 and comprises as the illumination element 25 a light permeable illumination surface that is backlit by a light source in the form of multi-color LEDs. This illumination surface surrounds the at least substantially round push button 21 in annular form. The supply of the display apparatus 23 with power can take place via the same power supply 27 that is also provided for the magnetic drive and for the heating apparatus 15. As long as the magnetic stirrer is switched on, the display apparatus 23 is fed by this power supply 27.

The display apparatus 23 is configured to light continuously with a constant brightness and color, for example red, on a switching on of the heating apparatus 15 and for the duration of the switched on state of the heating apparatus 15. A switched off state of the heating apparatus 15 can furthermore generally be indicated by the display apparatus 23 in that it is not illuminated. A distinction can at least be made in this manner with reference to the display apparatus 23 whether the switched on heating state or the switched off heating state of the heating apparatus 15 is present.

In addition, the display apparatus 23 is, however, also configured to display a respective temperature state of the placement surface at least when the heating apparatus 15 is switched off. If the heating apparatus 15 has heated the placement surface 17 and is then switched off, the placement surface 17 can have a residual heat that only gradually drops. To optionally warn of the residual het in order to avoid any painful touching of the still hot placement surface 17, the display apparatus 23 can control the illumination element 25 to transmit light with an illumination characteristic different from said constant illumination for at least as long as the placement surface 17 has an unpleasantly high temperature.

In this respect, a high residual heat, that is a respective temperature of the heatable placement surface 17 in a high temperature range, for example above 100° C., is in particular signaled by an illumination of the illumination surface of the display apparatus 23 flashing at a high frequency, for example approximately 5 Hz. A reduction of the temperature over time can further be indicated in that the flashing frequency drops correspondingly continuously or in steps. The flashing frequency can, for example, amount to 4 Hz for temperatures between 80° C. and 100° C., to 3 Hz for temperatures between 60° C. and 80° C., to 2 Hz for temperatures between 50° C. and 60° C., to 1 Hz for temperatures between 40° C. and 50° C. and to 0.5 Hz for temperatures between 30° C. and 40° C. Different comparable associations of the flashing frequencies with temperature ranges can, however, also be present.

To detect the respective temperature of the placement surface 17, the magnetic stirrer 11 has a temperature sensor in the region of the heating apparatus 15, said temperature sensor being arranged directly beneath the placement surface 17 and therefore not being visible. The display apparatus 23 can determine the presence of a respective one of a plurality of predefined temperature states of the placement surface 17 with reference to temperature signals that the temperature sensor generates and outputs in dependence on the respective temperature of the placement surface 17 and can then display this respective temperature state in accordance with an illumination characteristic associated therewith.

In addition to and in parallel with the reduction of the flashing frequency, the color of the light transmitted by the multi-color LEDs additionally changes from red over orange to yellow. Provision can furthermore generally be made that the illumination element 25 transmits green light for a predefined time period, for example for 10 s, before it is fully extinguished after falling below a specific temperature, e.g. approximately 30° C. The at least substantially complete cooling of the placement surface 17 can hereby be separately signaled.

Whether the heating apparatus 15 is actually switched on or switched off and whether, in the latter case, the placement surface 17 still has a dangerously or unpleasantly high residual heat or has already cooled so much that a user can touch it without injury can be seen directly from the magnetic stirrer 11 by means of the different illumination characteristics transmitted by the display apparatus 23.

So that a warning of a hot placement surface 17 is still also possible when the magnetic stirrer 11 is completely switched off, the display apparatus 23 is not supplied with power via the general power supply 27, bur is rather electrically connected to an energy converter 29 configured as a thermoelectric generator (cf. FIG. 2). Said energy converter 29 is suitable to at least partly convert the residual heat present at the placement surface 17 or at another part of the heating apparatus 15 after the heating up into electrical energy with which then the display apparatus 23 can be fed independently of the general power supply 27.

The two different manners of supplying the display apparatus 23 with power can be recognized in the embodiment of a magnetic stirrer 11 shown schematically in FIG. 2. This embodiment largely corresponds to the embodiment shown in FIG. 1 so that the same reference numerals are used for mutually corresponding elements.

Unlike in the embodiment of FIG. 1, in the embodiment shown in FIG. 2, the actuation element 21 is not configured as a push button or as a touch element, but rather as a rotary button. It can, for example, be used beyond the mere switching on or off for a regulation, e.g. of the strength of the heating power. The display apparatus 23 is configured as an illuminated ring surrounding the rotary button 21. The display apparatus 23 can, however, generally also be implemented as a separate display unit, for example as an LED.

In the schematic representation of FIG. 2, the power supply 27 can, on the one hand, be seen in the interior of the base unit 13 of the magnetic stirrer 11 that is configured as a power part and that can be connected to an outlet via a cable. The electrical connection between the power supply 27 and the display apparatus 23 is shown as a dashed line. On the other hand, it can be recognized in FIG. 2 that a foot section 31 of the heating apparatus 15 is inserted into the base unit 13. The residual heat present at the placement surface 17 after a heating can be substantially irradiated only either to the environment or dissipated by heat conduction via the foot section 31 from the placement surface 17. A temperature gradient is therefore formed between the placement surface 17 and a region of the foot section 31 facing away from the placement surface 17. The foot section 31 can to this extent act as a heat dissipation apparatus for the placement surface 17.

Said temperature gradient can be tapped by the only schematically shown energy converter 29 that is arranged at the foot section 31 and can be used to at least partly convert the residual heat into electrical energy. A further energy source is thus available for the display apparatus 23 that only depends on whether a sufficient residual heat is still present at the placement surface 17 that is, however, independent of the general power supply 27. The energy converter 29 is connected to the display apparatus 23 via a further electrical connection shown schematically by a dashed line.

The display apparatus 23 can also still warn of the temperature state of the placement surface 17, in particular by lamps, with a switched off power supply 27 due to such a configuration in accordance with the invention as long as said placement surface 17 still has such a residual heat that it should e.g. in particular not be touched. The independence of the display apparatus 23 from the general power supply 27 thus achieved thus provides improved security of the magnetic stirrer 11.

### REFERENCE NUMERAL LIST

11 magnetic stirrer
13 base unit
15 heating apparatus
17 placement surface
19 operating surface
21 actuation element
23 display apparatus
25 illumination element
27 power supply
29 energy converter
31 foot section

1. A laboratory device, in particular a magnetic stirrer (11), comprising an outer surface section, in particular a placement surface for a vessel, wherein the laboratory device (11) comprises a display apparatus (23) that is configured to display a respective temperature state of the outer surface section (17),
characterized in that
the laboratory device (11) is configured to utilize at least also heat of the outer surface section (17) for the energy supply of the display apparatus (23).

2. A laboratory device in accordance with claim 1,
characterized in that
the laboratory device (11) comprises a heating apparatus (15) that is configured to heat the outer surface section (17) to heat up the substance.

3. A laboratory device in accordance with claim 1 or claim 2,
characterized in that
the laboratory device (11) comprises a heat dissipation apparatus for the outer surface section (17) and is configured to utilize a temperature gradient between the outer surface section (17) and the heat dissipation apparatus for the energy supply of the display apparatus (23).

4. A laboratory device in accordance with at least one of the preceding claims,
characterized in that
the laboratory device (11) comprises an energy converter (29) that is configured to convert heat of the outer surface section (17) into energy usable for the energy supply of the display apparatus (23) and to supply the energy to the display apparatus (23).

5. A laboratory device in accordance with claim 3 and claim 4,
characterized in that
the energy converter (29) is in a thermal relationship, in particular in thermal contact, with the outer surface section (17), on the one hand, and with the heat dissipation apparatus, on the other hand.

6. A laboratory device in accordance with claim 4 or claim 5,
characterized in that
the energy converter (29) is configured as a thermoelectric generator, in particular in the manner of a Peltier element.

7. A laboratory device in accordance with at least one of the preceding claims,
characterized in that
the display apparatus (23) comprises an illumination element (25) controllable to transmit light, in particular at least one LED,
with the display apparatus (23) being configured to control the illumination element (25) to transmit light having respectively different illumination characteristics for the display of different temperature states of the outer surface section (17) and/or of different heating states of a heating apparatus (15) of the laboratory device (11).

8. A laboratory device in accordance with claim 7,
characterized in that
the display apparatus (23) is configured to control the illumination element (25) to transmit light in accordance with a first illumination characteristic, in particular constantly illuminating light, for the display of a switched on state of the heating apparatus (15), to control the illumination element (25) to transmit light in accordance with a second illumination characteristic, in particular pulsating light, for a combined display of a switched off state of the heating device (15) and a hot state of the outer surface section (17);
and/or to control the illumination element (25) to transmit light in accordance with a third illumination characteristic, in particular no light, for a combined display of a switched off state of the heating apparatus (15) and a cool state of the outer surface section (17).

9. A laboratory device in accordance with claim 7 or claim 8,
characterized in that
the display apparatus (23) is configured to control the illumination element (25) to transmit pulsating light of different pulse frequencies for the combined display of a switched off state of the heating apparatus (15) and of different hot states of the outer surface section (17).

10. A laboratory device in accordance with any one of the claims 7 to 9,
characterized in that
respective illumination characteristics for displaying different temperature states of the outer surface section (17) differ with respect to the pulse frequency, the color and/or the brightness of the respective light transmitted by the illumination element (25).

11. A laboratory device in accordance with at least one of the preceding claims,
characterized in that
the laboratory device (11) comprises an actuation element (21), in particular for switching and/or adjusting a heating apparatus (15) of the laboratory device (11),
with the display apparatus (23) being provided at the actuation element (21), in particular being arranged encompassing the actuation element (21) or being integrated in the actuation element (21).

12. A laboratory device in accordance with at least one of the preceding claims,
characterized in that
the laboratory device (11) comprises a temperature sensor for detecting a respective temperature of the outer surface section (17),
with the display apparatus (23) being configured to determine and display the respective temperature state of the outer surface section (17) in dependence on the respective temperature detected by means of the temperature sensor.

13. A laboratory device in accordance with at least one of the preceding claims,
characterized in that
the laboratory device (11) comprises a base unit (13) having at least one power supply for an optional magnetic drive and a heating apparatus (15), with the heating apparatus (15), in particular a hotplate, being formed separately from the base unit (13), and being arranged at the base unit (13), and having the outer surface section (17);
and with the display apparatus (23) being provided at the base unit (13).
